(19) United States
(12) Patent Application Publication
(10) Pub. No.: US 2025/0063741 A1
(43) Pub. Date: Feb. 20, 2025

(54) SEMICONDUCTOR DEVICE AND MANUFACTURING METHOD OF THE SEMICONDUCTOR DEVICE

(71) Applicant: SK hynix Inc., Icheon-si (KR)

(72) Inventors: Sang Chul OH, Icheon-si (KR); Myoungsub KIM, Icheon-si (KR)

(21) Appl. No.: 18/537,555

(22) Filed: Dec. 12, 2023

(30) Foreign Application Priority Data
Aug. 18, 2023 (KR) 10-2023-0108007

(51) Int. Cl. H10B 63/00; H10B 61/00

(52) U.S. Cl. CPC H10B 63/80; H10B 61/00

(57) ABSTRACT

A semiconductor device may include: a first conductive line; a second conductive line located over the first conductive line, wherein the first conductive line and the second conductive line extend in different directions, intersecting each other; a variable resistance pattern located between the first conductive line and the second conductive line; a first electrode pattern located between the first conductive line and the variable resistance pattern; a first resistivity barrier pattern located between the first conductive line and the first electrode pattern; and a first diffusion barrier pattern located between the first resistivity barrier pattern and the first electrode pattern.

### CROSS-REFERENCE TO RELATED APPLICATION

This application claims priority under 35 U.S.C. § 119 to Korean Patent Application No. 10-2023-0108007 filed on Aug. 18, 2023, which is incorporated herein by reference in its entirety.

### BACKGROUND

### 1. Technical Field

Embodiments of the present disclosure relate to an electronic device and a manufacturing method of the electronic device, and more particularly, to a semiconductor device and a manufacturing method of the semiconductor device.

### 2. Related Art

The degree of integration of a semiconductor device is mainly determined by an area occupied by a unit memory cell. Recently, as the improvement in the degree of integration of a semiconductor device for forming memory cells in a single layer on a substrate reaches a limit, a three-dimensional semiconductor device for stacking memory cells on a substrate has been proposed. Furthermore, in order to improve the operational reliability of such a semiconductor device, various structures and manufacturing methods have been developed.

### SUMMARY

In an embodiment, a semiconductor device may include: a first conductive line; a second conductive line located over the first conductive line, wherein the first conductive line and the second conductive line extend in different directions, intersecting each other; a variable resistance pattern located between the first conductive line and the second conductive line; a first electrode pattern located between the first conductive line and the variable resistance pattern; a first resistivity barrier pattern located between the first conductive line and the first electrode pattern; and a first diffusion barrier pattern located between the first resistivity barrier pattern and the first electrode pattern.

In an embodiment, a manufacturing method of a semiconductor device, the manufacturing method comprising: forming a first resistivity barrier layer over a first conductive layer; forming a first diffusion barrier layer over the first resistivity barrier layer; forming a first electrode layer over the first diffusion barrier layer; forming a variable resistance layer over the first electrode layer; forming a second electrode layer over the variable resistance layer; and forming a second conductive layer over the second electrode layer.

In an embodiment, a manufacturing method comprising: forming a first conductive layer; forming a first resistivity barrier layer over the first conductive layer; forming a first diffusion barrier layer over the first resistivity barrier layer; forming a first electrode layer over the first diffusion barrier layer; forming a variable resistance layer over the first electrode layer; forming a second electrode layer over the variable resistance layer; forming a memory line that includes a second electrode line, a variable resistance line, and a first electrode line by etching the second electrode layer, the variable resistance layer, and the first electrode layer in a first direction; forming a first diffusion barrier line and a first resistivity barrier line by etching the first diffusion barrier layer and the first resistivity barrier layer in the first direction; forming a second conductive layer over the memory line; forming a second conductive line by etching the second conductive layer in a second direction that intersects the first direction; forming a memory cell that includes a second electrode pattern, a variable resistance pattern, and a first electrode pattern by etching the memory line in the second direction; and forming a first diffusion barrier pattern and a first resistivity barrier pattern by etching the first diffusion barrier line and the first resistivity barrier line in the second direction.

### BRIEF DESCRIPTION OF THE DRAWINGS

FIGS. 1A and 1B illustrate a semiconductor device in accordance with an embodiment.

FIGS. 2A and 2B illustrate a semiconductor device in accordance with another embodiment.

FIGS. 3A and 3B each illustrate a semiconductor device in accordance with still another embodiment.

FIG. 4 illustrates a manufacturing method of a semiconductor device in accordance with an embodiment.

FIG. 5A, FIG. 5B, FIG. 6A, FIG. 6B, FIG. 7A, FIG. 7B, FIG. 8A, FIG. 8B, FIG. 9A, and FIG. 9B illustrate a manufacturing method of a semiconductor device in accordance with an embodiment.

### DETAILED DESCRIPTION

Various embodiments are directed to a semiconductor device having a stable structure and improved characteristics and a manufacturing method of the semiconductor device.

According to the present technology, it is possible to provide a semiconductor device having a stable structure and improved reliability.

Hereafter, embodiments in accordance with the technical spirit of the present disclosure will be described with reference to the accompanying drawings.

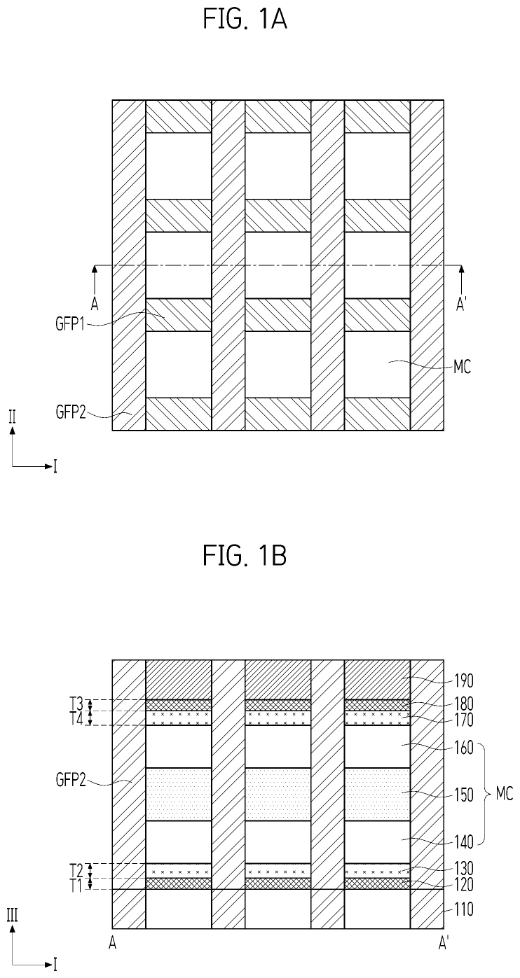

FIGS. 1A and 1B illustrate a semiconductor device in accordance with an embodiment. FIG. 1A is a plan view, and FIG. 1B is a cross-sectional view taken along line A-A′ of FIG. 1A.

Referring to FIGS. 1A and 1B, the semiconductor device may include a first conductive line 110, a second conductive line 190, a memory cell MC, or a combination thereof over a substrate (not illustrated). The semiconductor device may further include a first gap fill pattern GFP1, a second gap fill pattern GFP2, a first resistivity barrier pattern 120, a first diffusion barrier pattern 130, a second resistivity barrier pattern 180, a second diffusion barrier pattern 170, or a combination thereof. Here, the memory cell MC may include a first electrode pattern 140, a variable resistance pattern 150, a second electrode pattern 160, or a combination thereof.

The first conductive line 110 may be a word line or a bit line. The second conductive line 190 may be located over the first conductive line 110. The second conductive line 190 may intersect the first conductive line 110 when viewed in a plan view. The second conductive line 190 may be a bit line or a word line. For example, when the first conductive line 110 is a word line, the second conductive line 190 may be a bit line. On the other hand, when the first conductive line 110 is a bit line, the second conductive line 190 may be a word line.

The variable resistance pattern 150 may be located between the first conductive line 110 and the second conductive line 190 in a third direction (or vertical direction) III that is perpendicular to a top surface of the substrate. The variable resistance pattern 150 may include a resistive material and switch between different resistance states based on an applied voltage or current.

The variable resistance pattern 150 may include transition metal oxide or other metal oxides, such as those based on perovskite materials. Accordingly, an electrical path is created or disappears in the variable resistance pattern 150, such that data may be stored in the memory cell MC.

The variable resistance pattern 150 may have a magnetic tunnel junction (MTJ) structure that includes a magnetization pinned layer, a magnetization free layer, and a tunnel barrier layer interposed between the magnetization pinned layer and the magnetization free layer. For example, the magnetization pinned layer and the magnetization free layer may each include a magnetic material, and the tunnel barrier layer may include oxide of magnesium (Mg), aluminum (Al), zinc (Zn), titanium (Ti), or the like. Here, a magnetization direction of the magnetization free layer may be changed by spin torque of electrons in the applied current. Accordingly, the data may be stored in the memory cell MC based on a change in the magnetization direction of the magnetization free layer relative to a magnetization direction of the magnetization pinned layer.

The variable resistance pattern 150 may include a phase change material or chalcogenide. The variable resistance pattern 150 may include chalcogenide glass, chalcogenide alloy, or the like. The variable resistance pattern 150 may include elements including, but not limited thereto, silicon (Si), germanium (Ge), antimony (Sb), tellurium (Te), bismuth (Bi), indium (In), tin (Sn), selenium (Se), or a combination thereof. The variable resistance pattern 150 may be made of Ge—Sb—Te (GST) such as Ge₂Sb₂Te₅, Ge₂Sb₂Te₇, Ge₁Sb₂Te₄, or Ge₁Sb₄Te₇. The variable resistance pattern 150 may change its phase according to a program operation. For example, the variable resistance pattern 150 may have a low-resistance crystalline state by a set operation. On the other hand, the variable resistance pattern 150 may have a high-resistance amorphous state by a reset operation. Accordingly, the data may be stored in the memory cell MC based on the resistance difference corresponding to the phase of the variable resistance pattern 150.

The variable resistance pattern 150 may be composed of a material that changes resistance without undergoing a phase change or of a chalcogenide-based material. The variable resistance pattern 150 may include elements including, but not limited thereto, germanium (Ge), antimony (Sb), tellurium (Te), arsenic (As), selenium (Se), silicon (Si), indium (In), tin (Sn), sulfur(S), gallium (Ga), or a combination thereof.

The variable resistance pattern 150 may include chalcogenide that retains an amorphous state during a program operation. Therefore, during the program operation, the variable resistance pattern 150 may remain in the amorphous state and not transition to a crystalline state. Accordingly, a threshold voltage of the memory cell MC may be changed depending on a program voltage applied to the memory cell MC, and the memory cell MC may be programmed to one of at least two states. For example, when a negative program voltage is applied to the memory cell MC, the memory cell MC may have a relatively high threshold voltage. On the other hand, when a positive program voltage is applied to the memory cell MC, the memory cell MC may have a relatively low threshold voltage. Accordingly, the data may be stored in the memory cell MC based on a difference in the threshold voltage of the memory cell MC.

The first electrode pattern 140 may be located over the first conductive line 110. For example, the first electrode pattern 140 may be located between the first conductive line 110 and the variable resistance pattern 150 in the third direction III. The first electrode pattern 140 may be a portion of a word line or a bit line, or may be electrically connected to the word line or the bit line. The first electrode pattern 140 may include a conductive material such as polysilicon or metal. For example, the first electrode pattern 140 may include elements including, but not limited thereto, polysilicon, tungsten (W), tungsten nitride (WNₓ), tungsten silicide (WSiₓ), titanium (Ti), titanium nitride (TiNₓ), titanium silicon nitride (TiSiN), titanium aluminum nitride (TiAlN), tantalum (Ta), tantalum nitride (TaN), tantalum silicon nitride (TaSiN), tantalum aluminum nitride (TaAlN), carbon (C), silicon carbide (SIC), silicon carbonitride (SiCN), copper (Cu), zinc (Zn), nickel (Ni), cobalt (Co), lead (Pb), platinum (Pt), molybdenum (Mo), ruthenium (Ru), or a combination thereof.

The second electrode pattern 160 may be located below the second conductive line 190 in the third direction III. For example, the second electrode pattern 160 may be located between the variable resistance pattern 150 and the second conductive line 190. The second electrode pattern 160 may be a portion of a bit line or a word line, or may be electrically connected to the bit line or the word line. For example, when the first electrode pattern 140 is electrically connected to the word line, the second electrode pattern 160 may be electrically connected to the bit line. The second electrode pattern 160 may include a conductive material such as polysilicon or metal. For example, the second electrode pattern 160 may include elements including, but not limited thereto, polysilicon, tungsten (W), tungsten nitride (WNₓ), tungsten silicide (WSiₓ), titanium (Ti), titanium nitride (TiNₓ), titanium silicon nitride (TiSiN), titanium aluminum nitride (TiAlN), tantalum (Ta), tantalum nitride (TaN), tantalum silicon nitride (TaSiN), tantalum aluminum nitride (TaAlN), carbon (C), silicon carbide (SiC), silicon carbonitride (SiCN), copper (Cu), zinc (Zn), nickel (Ni), cobalt (Co), lead (Pb), platinum (Pt), molybdenum (Mo), ruthenium (Ru), or a combination thereof.

The first gap fill pattern GFP1 may be located between memory cells MC that are adjacent to each other in a second direction II. The second gap fill pattern GFP2 may be located between memory cells MC that are adjacent to each other in a first direction I, which intersects the second direction II. The first gap fill pattern GFP1, the second gap fill pattern GFP2, or both may include an insulating material. For example, the first gap fill pattern GFP1, the second gap fill pattern GFP2, or both may include oxide. The first direction I and the second direction II are parallel to the top surface of the substrate, and thus they are perpendicular to the third direction III.

The first resistivity barrier pattern 120 may be located over the first conductive line 110 in the third direction III. For example, the first resistivity barrier pattern 120 may be located between the first conductive line 110 and the first electrode pattern 140. The first resistivity barrier pattern 120 may have a first thickness T1. The first resistivity barrier pattern 120 may include WSiN.

The memory cell MC may operate by receiving a current supplied through the first conductive line 110. When the memory cell MS operates, a spike current may occur. The first resistivity barrier pattern 120 may prevent or reduce damage to the memory cell MC due to the spike current. For example, the first resistivity barrier pattern 120 may reduce transmission of the spike current to the memory cell MC through the first conductive line 110 since it is located between the memory cell MC and the first conductive line 110. Accordingly, the first resistivity barrier pattern 120 may have a relatively high resistivity.

When the memory cell MC is repeatedly operated, the first resistivity barrier pattern 120 may deteriorate due to Joule heating and electrical stress. For example, the first resistivity barrier pattern 120 may agglomerate. When the first resistivity barrier pattern 120 deteriorates, an element in the first resistivity barrier pattern 120 may be diffused into the memory cell MC. For example, the element in the first resistivity barrier pattern 120 may be diffused into the variable resistance pattern 150. For example, when the first resistivity barrier pattern 120 includes WSiN, at least one of tungsten (W) and silicon (Si) may be diffused into the variable resistance pattern 150.

When the element in the first resistivity barrier pattern 120 is diffused into the variable resistance pattern 150, the variable resistance pattern 150 may be damaged. In order to reduce the damage to the variable resistance pattern 150, the first diffusion barrier pattern 130 may be located between the first resistivity barrier pattern 120 and the variable resistance pattern 150. The first diffusion barrier pattern 130 may prevent the element in the first resistivity barrier pattern 120 from being diffused into the variable resistance pattern 150. Accordingly, it is possible to prevent the memory cell MC from being damaged by the element in the first resistivity barrier pattern 120.

When the first diffusion barrier pattern 130 is located between the first resistivity barrier pattern 120 and the variable resistance pattern 150, the first electrode pattern 140 may be located between the first diffusion barrier pattern 130 and the variable resistance pattern 150.

The first diffusion barrier pattern 130 may have a second thickness T2. The second thickness T2 may be substantially the same as or different from the first thickness T1 of the first resistivity barrier pattern 120. For example, the second thickness T2 may be greater than the first thickness T1. A resistivity of the first diffusion barrier pattern 130 may be substantially the same as or different from the resistivity of the first resistivity barrier pattern 120. For example, the resistivity of the first diffusion barrier pattern 130 may be lower than the resistivity of the first resistivity barrier pattern 120. The first diffusion barrier pattern 130 may include tungsten nitride (WN) or titanium nitride (TiN).

A grain boundary in the first diffusion barrier pattern 130 may be used as a path for the element from the first resistivity barrier pattern 120 to diffuse into the variable resistance pattern 150. Accordingly, according to an embodiment of the present disclosure, another element may be located at a grain boundary of a metal element within the first diffusion barrier pattern 130. For example, a nitrogen element (N) may be located at a grain boundary of tungsten (W) or titanium (Ti). By blocking the diffusion path along the grain boundary using the nitrogen element (N), it is possible to reduce the diffusion of the element from the first resistivity barrier pattern 120. In other words, the first diffusion barrier pattern 130 may reduce or prevent the diffusion of the element from the first resistivity barrier pattern 120 into the variable resistance pattern 150, and thus may prevent the memory cell MC from being damaged.

The second resistivity barrier pattern 180 may be located below the second conductive line 190 in the third direction III. For example, the second resistivity barrier pattern 180 may be located between the second conductive line 190 and the second electrode pattern 160. The second resistivity barrier pattern 180 may have a third thickness T3. The third thickness T3 may be substantially the same as or different from the first thickness T1. For example, the third thickness T3 may be substantially the same as the first thickness T1. The second resistivity barrier pattern 180 may include a material similar to that of the first resistivity barrier pattern 120. For example, the second resistivity barrier pattern 180 may include WSiN.

The second resistivity barrier pattern 180 may reduce transmission of a spike current to the memory cell MC through the second conductive line 190 since it is located between the memory cell MC and the second conductive line 190. Accordingly, the second resistivity barrier pattern 180 may have a relatively high resistivity. In addition, an element in the second resistivity barrier pattern 180, e.g., tungsten (W), silicon (Si), or both, may be diffused into the variable resistance pattern 150.

The second diffusion barrier pattern 170 may be located between the second resistivity barrier pattern 180 and the variable resistance pattern 150 in the third direction III. For example, the second diffusion barrier pattern 170 may be located between the second resistivity barrier pattern 180 and the second electrode pattern 160. The second diffusion barrier pattern 170 may have a fourth thickness T4. The fourth thickness T4 may be substantially the same as or different from the third thickness T3. For example, the fourth thickness T4 may be greater than the third thickness T3. A resistivity of the second diffusion barrier pattern 170 may be substantially the same as or different from a resistivity of the second resistivity barrier pattern 180. For example, the resistivity of the second diffusion barrier pattern 170 may be lower than the resistivity of the second resistivity barrier pattern 180. The second diffusion barrier pattern 170 may include tungsten nitride (WN) or titanium nitride (TN). The second diffusion barrier pattern 170 may prevent the element in the second resistivity barrier pattern 180 from being diffused into the variable resistance pattern 150.

According to other embodiments, at least one of the first resistivity barrier pattern 120, the first diffusion barrier pattern 130, the second resistivity barrier pattern 180, and the second diffusion barrier pattern 170 may be omitted. For example, the first resistivity barrier pattern 120 and the first diffusion barrier pattern 130 may be located between the first conductive line 110 and the first electrode pattern 140, and the second resistivity barrier pattern 180 and the second diffusion barrier pattern 170 may be omitted. In an alternate configuration, the second resistivity barrier pattern 180 and the second diffusion barrier pattern 170 may be located between the second conductive line 190 and the second electrode pattern 160, and the first resistivity barrier pattern 120 and the first diffusion barrier pattern 130 may be omitted.

Alternatively, a location of at least one of the first resistivity barrier pattern 120, the first diffusion barrier pattern 130, the second resistivity barrier pattern 180, and the second diffusion barrier pattern 170 may be changed. For example, the first resistivity barrier pattern 120 may be located between the first conductive line 110 and the first electrode pattern 140, and the first diffusion barrier pattern 130 may be located between the first electrode pattern 140 and the variable resistance pattern 150. Here, the second resistivity barrier pattern 180 may be located between the second conductive line 190 and the second electrode pattern 160, and the second diffusion barrier pattern 170 may be located between the second electrode pattern 160 and the variable resistance pattern 150. In an alternate configuration, the first resistivity barrier pattern 120 and the first diffusion barrier pattern 130 may be located between the first electrode pattern 140 and the variable resistance pattern 150, and the second resistivity barrier pattern 180 and the second diffusion barrier pattern 170 may be located between the second electrode pattern 160 and the variable resistance pattern 150.

According to the structure described above, the first diffusion barrier pattern 130 may be located between the first resistivity barrier pattern 120 and the first electrode pattern 140, and the second diffusion barrier pattern 170 may be located between the second resistivity barrier pattern 180 and the second electrode pattern 160. Accordingly, the first diffusion barrier pattern 120 may reduce the diffusion of the element from the first resistivity barrier pattern 120 into the variable resistance pattern 150, and the second diffusion barrier pattern 170 may reduce the diffusion of the element from the second resistivity barrier pattern 180 into the variable resistance pattern 150. As a result, it is possible to reduce or prevent the damage to the memory cell MC.

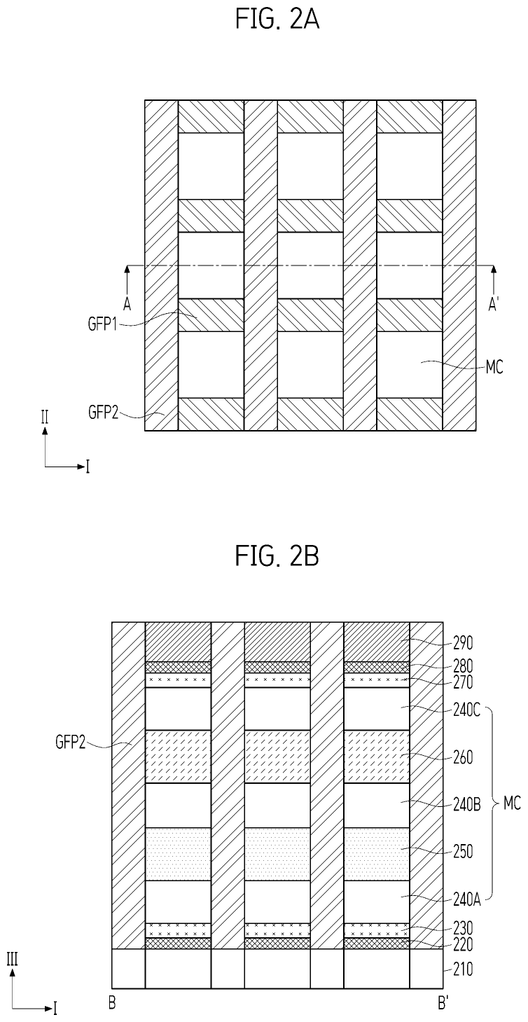

FIGS. 2A and 2B illustrate a semiconductor device in accordance with another embodiment. FIG. 2A is a plan view, and FIG. 2B is a cross-sectional view taken along line B-B′ of FIG. 2A. Hereinafter, the content overlapping with the previously described content will be omitted.

Referring to FIGS. 2A and 2B, the semiconductor device may include a first conductive line 210, a second conductive line 290, a memory cell MC, or a combination thereof over a substrate (not illustrated). The semiconductor device may further include a first gap fill pattern GFP1, a second gap fill pattern GFP2, a first resistivity barrier pattern 220, a first diffusion barrier pattern 230, a second resistivity barrier pattern 280, a second diffusion barrier pattern 270, or a combination thereof. Here, the memory cell MC may include a first electrode pattern 240A, a first variable resistance pattern 250, a second electrode pattern 240B, a second variable resistance pattern 260, a third electrode pattern 240C, or a combination thereof.

The first resistivity barrier pattern 220, the first diffusion barrier pattern 230, or both may be located between the first conductive line 210 and the first electrode pattern 240A in the third direction III. For example, the first resistivity barrier pattern 220 may be located on the first conductive line 210, and the first diffusion barrier pattern 230 may be located between the first resistivity barrier pattern 220 and the first electrode pattern 240A. The first variable resistance pattern 250 may be located on the first electrode pattern 240A, and the second electrode pattern 240B may be located on the first variable resistance pattern 250.

A selection element may include the first electrode pattern 240A, the first variable resistance pattern 250, the second electrode pattern 240B, or a combination thereof. The selection element may be a diode, a positive-negative-positive (PNP) diode, a transistor, a vertical transistor, a bipolar junction transistor (BJT), a metal insulator transition (MIT) element, a mixed ionic-electronic conduction (MIEC) element, an Ovonic threshold switching (OTS) element, or the like. The first variable resistance pattern 250 may include a chalcogenide material. The first electrode pattern 240A may be a lower electrode, and the second electrode pattern 240B may be an intermediate electrode. The first electrode pattern 240A, the second electrode pattern 240B, or both may include metal or metal nitride.

The second resistivity barrier pattern 280, the second diffusion barrier pattern 270, or both may be located between the second conductive line 290 and the third electrode pattern 240C in the third direction III. For example, the second resistivity barrier pattern 280 may be located below the second conductive line 290, and the second diffusion barrier pattern 270 may be located between the second resistivity barrier pattern 280 and the third electrode pattern 240C. The second variable resistance pattern 260 may be located between the second electrode pattern 240B and the third electrode pattern 240C.

A memory element may include the second electrode pattern 240B, the second variable resistance pattern 260, the third electrode pattern 240C, or a combination thereof. The memory element may share the second electrode pattern 240B with the selection element. The second variable resistance pattern 260 may include a chalcogenide material. The third electrode pattern 240C may be an upper electrode. The third electrode pattern 240C may include metal or metal nitride.

The first diffusion barrier pattern 230, the second diffusion barrier pattern 270, or both may include tungsten nitride (WN) or titanium nitride (TiN). The first resistivity barrier pattern 220, the second resistivity barrier pattern 280, or both may include WSiN. The first diffusion barrier pattern 230 may reduce diffusion of an element from the first resistivity barrier pattern 220 into the memory cell MC. The second diffusion barrier pattern 270 may reduce diffusion of an element from the second resistivity barrier pattern 280 into the memory cell MC. Here, the element in the first resistivity barrier pattern 220, the element in the second resistivity barrier pattern 280, or both may include at least one of tungsten and silicon. Accordingly, the diffusion barrier patterns 230 and 270 may reduce the diffusion of the elements from the resistivity barrier patterns 220 and 280 into the variable resistance patterns 250 and 260, respectively, to reduce or prevent damage to the memory cell MC.

According to other embodiments, at least one more of the first resistivity barrier pattern 220, the first diffusion barrier pattern 230, the second resistivity barrier pattern 280, and the second diffusion barrier pattern 270 may be omitted. Alternatively, a location of at least one of the first resistivity barrier pattern 220, the first diffusion barrier pattern 230, the second diffusion barrier pattern 270, and the second resistivity barrier pattern 280 may be changed.

According to the structure described above, the memory cell MC may be composed of the memory element and the selection element. The first resistivity barrier pattern 220 may be located between the first conductive line 210 and the memory cell MC, and the first diffusion barrier pattern 230 may be located between the first resistivity barrier pattern 220 and the memory cell MC. The second resistivity barrier pattern 280 may be located between the second conductive line 290 and the memory cell MC, and the second diffusion barrier pattern 270 may be located between the second resistivity barrier pattern 280 and the memory cell MC. Accordingly, the diffusion barrier patterns 230 and 270 may reduce or prevent the diffusion of the elements from the resistivity barrier patterns 220 and 280 into the variable resistance patterns 250 and 260 of the memory cell MC, respectively, to prevent the memory cell MC from being damaged.

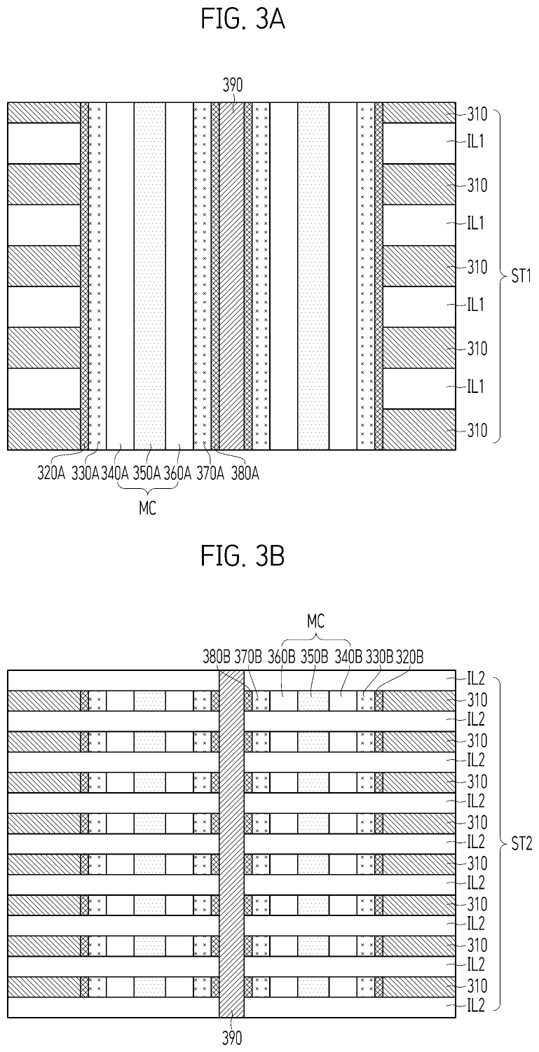

FIGS. 3A and 3B each illustrate a semiconductor device in accordance with still another embodiment. Hereinafter, the content overlapping with the previously described content will be omitted.

Referring to FIGS. 3A and 3B, the semiconductor device may have a stacked structure in which a plurality of memory cells are stacked in a vertical direction with respect to the orientation of FIGS. 3A and 3B. The vertical direction may be perpendicular to a top surface of a substrate (not illustrated).

Referring to FIG. 3A, the semiconductor device may include a stack ST1, a memory cell part MCS, a first resistivity barrier pattern 320A, a first diffusion barrier pattern 330A, a second resistivity barrier pattern 380A, a second diffusion barrier pattern 370A, or a combination thereof. Here, the memory cell part MCS may include a first electrode pattern 340A, a second electrode pattern 360A, a variable resistance pattern 350A, or a combination thereof.

The stack ST1 may include first conductive lines 310 and insulating layers IL1 that are alternately stacked in the vertical direction. The first conductive lines 310 may each include a conductive material such as polysilicon or metal. The first conductive lines 310 may each include elements including, but not limited thereto, polysilicon, tungsten (W), tungsten nitride (WNₓ), tungsten silicide (WSiₓ), titanium (Ti), titanium nitride (TiNₓ), titanium silicon nitride (TiSiN), titanium aluminum nitride (TiAlN), tantalum (Ta), tantalum nitride (TaN), tantalum silicon nitride (TaSiN), tantalum aluminum nitride (TaAlN), carbon (C), silicon carbide (SIC), silicon carbonitride (SiCN), copper (Cu), zinc (Zn), nickel (Ni), cobalt (Co), lead (Pb), platinum (Pt), molybdenum (Mo), ruthenium (Ru), or a combination thereof. For example, the first conductive lines 310 may each include carbon. The first conductive lines 310 may each be a word line or a bit line. The insulating layers IL1 are used to insulate the first conductive lines 310 from each other, and may each include an insulating material such as oxide or nitride.

A second conductive line 390 may be formed to penetrate through the stack ST1 in the vertical direction. Here, the structure of the second conductive line 390 may be filled up to a center region of the stack ST1. Therefore, the second conductive line 390 may extend in a direction intersecting the first conductive lines 310. The second conductive line 390 may include elements including, but not limited thereto, polysilicon, tungsten (W), tungsten nitride (WNₓ), tungsten silicide (WSiₓ), titanium (Ti), titanium nitride (TiNₓ), titanium silicon nitride (TiSiN), titanium aluminum nitride (TiAlN), tantalum (Ta), tantalum nitride (TaN), tantalum silicon nitride (TaSiN), tantalum aluminum nitride (TaAlN), carbon (C), silicon carbide (SIC), silicon carbonitride (SiCN), copper (Cu), zinc (Zn), nickel (Ni), cobalt (Co), lead (Pb), platinum (Pt), molybdenum (Mo), ruthenium (Ru), or a combination thereof. The second conductive line 390 may be a bit line or a word line. When the first conductive line 310 is a word line, the second conductive line 390 may be a bit line. On the other hand, when the first conductive line 310 is a bit line, the second conductive line 390 may be a word line.

Referring to FIG. 3A, the first electrode pattern 340A may be located between the first conductive lines 310 and the second conductive line 390 in a horizontal direction that is substantially perpendicular to the vertical direction. The first electrode pattern 340A may extend in a direction parallel to a direction in which the second conductive line 390 extends, and may surround a sidewall of the second conductive line 390. The direction in which the second conductive line 390 may correspond to the vertical direction.

The second electrode pattern 360A may be located between the first electrode pattern 340A and the second conductive line 390 in the horizontal direction. The second electrode pattern 360A may extend in the vertical direction, and may surround the sidewall of the second conductive line 390.

The variable resistance pattern 350A may be located between the first electrode pattern 340A and the second electrode pattern 360A in the horizontal direction. The variable resistance pattern 350A may extend in the vertical direction, and may surround the sidewall of the second conductive line 390.

The first resistivity barrier pattern 320A may be located between the first conductive lines 310 and the first electrode pattern 340A in the horizontal direction. The first resistivity barrier pattern 320A may extend in the vertical direction, and may surround an outer sidewall of the memory cell part MCS.

The first diffusion barrier pattern 330A may be located between the first resistivity barrier pattern 320A and the first electrode pattern 340A in the horizontal direction. The first diffusion barrier pattern 330A may extend in the vertical direction, and may surround the outer sidewall of the memory cell part MCS.

The second resistivity barrier pattern 380A may be located between the second conductive line 390 and the second electrode pattern 360A in the horizontal direction. The second resistivity barrier pattern 380A may extend in the vertical direction, and may surround an inner sidewall of the memory cell part MCS.

The second diffusion barrier pattern 370A may be located between the second resistivity barrier pattern 380A and the second electrode pattern 360A in the horizontal direction. The second diffusion barrier pattern 370A may extend in the vertical direction, and may surround the inner sidewall of the memory cell part MCS. The inner sidewall of the memory cell part MCS may be closer to the second conductive line 390 than the outer sidewall of the memory cell part MCS is.

In the embodiment illustrated in FIG. 3A, a memory cell may be defined as a portion of the memory cell part MCS that is disposed between each of the first conductive lines 310 and the second conductive line 390. Accordingly, the memory cell part MCS includes a plurality of memory cells that are disposed between the first conductive lines 310 and the second conductive line 390 and stacked in the vertical direction.

In the embodiment illustrated in FIG. 3B, a plurality of memory cells stacked in the vertical direction are separated from each other by insulating layers IL2 disposed therebetween in the vertical direction.

Referring to FIG. 3B, in each memory cell MC, a first electrode pattern 340B may be located between a corresponding one of the first conductive lines 310 and the second conductive line 390 in the horizontal direction. The first electrode pattern 340B may be located at substantially the same level as the corresponding one of the first conductive lines 310 in the vertical direction. The first electrode pattern 340B may surround a corresponding portion of the sidewall of the second conductive line 390. A second electrode pattern 360B may be located between the first electrode pattern 340B and the second conductive line 390 in the horizontal direction. The second electrode pattern 360B may surround the corresponding portion of the sidewall of the second conductive line 390. The variable resistance pattern 350B may be located between the first electrode pattern 340B and the second electrode pattern 360B in the horizontal direction. The variable resistance pattern 350B may surround the corresponding portion of the sidewall of the second conductive line 390. In the vertical direction, the corresponding portion of the sidewall of the second conductive line 390 may correspond to a thickness of the first conductive line 310.

A first resistivity barrier pattern 320B may be located between the corresponding one of the first conductive lines 310 and the first electrode pattern 340B. The first resistivity barrier pattern 320B may be located at substantially the same level as the corresponding one of the first conductive lines 310 in the vertical direction. The first resistivity barrier pattern 320B may surround an outer sidewall of the memory cell MC.

A first diffusion barrier pattern 330B may be located between the first resistivity barrier pattern 320B and the first electrode pattern 340B in the horizontal direction. The first diffusion barrier pattern 330B may surround the outer sidewall of the memory cell MC.

A second resistivity barrier pattern 380B may be located between the second conductive line 390 and the second electrode pattern 360B in the horizontal direction. The second resistivity barrier pattern 380B may surround an inner sidewall of the memory cell MC.

A second diffusion barrier pattern 370B may be located between the second resistivity barrier pattern 380B and the second electrode pattern 360B in the horizontal direction. The second diffusion barrier pattern 370B may surround the inner sidewall of the memory cell MC.

Referring to each of FIGS. 3A and 3B, the first diffusion barrier pattern, 330A or 330B, may reduce diffusion of an element from the first resistivity barrier pattern, 320A or 320B, into the memory cell MC. The second diffusion barrier pattern, 370A or 370B, may reduce diffusion of an element from the second resistivity barrier pattern, 380A or 380B, into the memory cell MC. Accordingly, the diffusion barrier patterns, 330A and 370A, or 330B and 370B, may reduce or prevent the diffusion of the elements from the resistivity barrier patterns, 320A and 380A, or 320B and 380B, into the variable resistance pattern, 350A or 350B, to reduce or prevent damage to the memory cell MC.

According to other embodiments, at least one of the first resistivity barrier pattern, the first diffusion barrier pattern, the second resistivity barrier pattern, and the second diffusion barrier pattern may be omitted. Alternatively, a location of at least one of the first resistivity barrier pattern, the first diffusion barrier pattern, the second diffusion barrier pattern, and the second resistivity barrier pattern may be changed.

According to the structure described above, the memory cell MC may be located in a region where a corresponding one of the first conductive lines 310 and the second conductive line 390 intersect each other. As shown in FIG. 3A, the memory cells MC disposed between the first conductive lines 310 and the second conductive line 390 may share the first resistivity barrier pattern 320A, the first diffusion barrier pattern 330A, the second resistivity barrier pattern 380A, and the second diffusion barrier pattern 370A with each other.

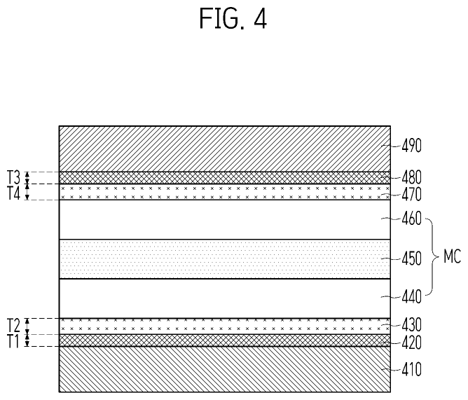

FIG. 4 illustrates a manufacturing method of a semiconductor device in accordance with an embodiment. Hereinafter, the content overlapping with the previously described content will be omitted.

Referring to FIG. 4, a first conductive layer 410 may be formed over a substrate (not illustrated). The first conductive layer 410 may be a word line or a bit line. A first resistivity barrier layer 420 may be formed on the first conductive layer 410. The first resistivity barrier layer 420 may be formed using at least one of a radio frequency (RF) sputtering method, a direct current (DC) sputtering method, an atomic layer deposition (ALD) method, and a chemical vapor deposition (CVD) method. The first resistivity barrier layer 420 may have a first thickness T1. The first resistivity barrier layer 420 may include WSiN.

A first diffusion barrier layer 430 may be formed on the first resistivity barrier layer 420. The first diffusion barrier layer 430 may be formed using at least one of an RF sputtering method, a DC sputtering method, an ALD method, and a CVD method. The first diffusion barrier layer 430 may have a second thickness T2. The second thickness T2 may be substantially the same as or different from the first thickness T1 of the first resistivity barrier layer 420. For example, the second thickness T2 may be greater than the first thickness T1. A resistivity of the first diffusion barrier layer 430 may be substantially the same as or different from a resistivity of the first resistivity barrier layer 420. For example, the resistivity of the first diffusion barrier layer 430 may be lower than the resistivity of the first resistivity barrier layer 420. The first diffusion barrier layer 430 may include tungsten nitride (WN) or titanium nitride (TIN).

A first electrode layer 440 may be formed on the first diffusion barrier layer 430. The first electrode layer 440 may be part of a word line or a bit line, or it may be electrically connected to the word line or the bit line. The first electrode layer 440 may include a conductive material such as polysilicon or metal. For example, the first electrode layer 440 may include polysilicon, tungsten (W), or the like.

A variable resistance layer 450 may be formed on the first electrode layer 440. The variable resistance layer 450 may include transition metal oxide or metal oxide such as a perovskite-based material. The variable resistance layer 450 may have an MTJ structure, and may include either a phase change material or chalcogenide that maintains an amorphous state during a program operation.

A second electrode layer 460 may be formed on the variable resistance layer 450. Consequently, a memory cell MC may be defined, which includes the first electrode layer 440, the variable resistance layer 450, and the second electrode layer 460. The second electrode layer 460 may be part of a word line or a bit line, or may be electrically connected to the word line or the bit line. When the first electrode layer 440 is electrically connected to the word line, the second electrode layer 460 may be electrically connected to the bit line. The second electrode layer 460 may include a conductive material such as polysilicon or metal. The second electrode layer 460 may include polysilicon, tungsten (W), or the like.

A second diffusion barrier layer 470 may be formed on the second electrode layer 460. The second diffusion barrier layer 470 may be formed using at least one of an RF sputtering method, a DC sputtering method, an ALD method, and a CVD method. The second diffusion barrier layer 470 may have a fourth thickness T4. The second diffusion barrier layer 470 may include tungsten nitride (WN) or titanium nitride (TIN).

A second resistivity barrier layer 480 may be formed on the second diffusion barrier layer 470. The second resistivity barrier layer 480 may be formed using at least one of an RF sputtering method, a DC sputtering method, an ALD method, and a CVD method. The second resistivity barrier layer 480 may have a third thickness T3. The third thickness T3 may be substantially the same as or different from the fourth thickness T4 of the second diffusion barrier layer 470. For example, the fourth thickness T4 may be greater than the third thickness T3. The second resistivity barrier layer 480 may include WSiN.

A second conductive layer 490 may be formed on the second resistivity barrier layer 480. The second conductive layer 490 may be patterned to intersect the first conductive layer 410 when viewed in a plan view. The second conductive layer 490 may be a bit line or a word line. For example, when the first conductive layer 410 is a word line, the second conductive layer 490 may be a bit line. On the other hand, when the first conductive layer 410 is a bit line, the second conductive layer 490 may be a word line.

The memory cell MC may operate by receiving a current supplied through the first conductive layer 410 or the second conductive layer 490. When the memory cell MC operates, a spike current may occur. Accordingly, in order to reduce transmission of the spike current to the memory cell MC through the first conductive layer 410 or the second conductive layer 490, the first resistivity barrier layer 420 may be formed between the first conductive layer 410 and the memory cell MC, and the second resistivity barrier layer 480 may be formed between the second conductive layer 490 and the memory cell MC. The resistivity barrier layers 420 and 480 may each include a material having a relatively high resistivity. For example, the resistivity barrier layers 420 and 480 may each include WSiN. Accordingly, the resistivity barrier layers 420 and 480 may prevent or reduce damage to the memory cell MC due to the spike current.

Meanwhile, when the memory cell MC repeatedly operates, the resistivity barrier layers 420 and 480 may deteriorate due to Joule heating and electrical stress. For example, the resistivity barrier layers 420 and 480 may agglomerate. When the resistivity barrier layers 420 and 480 deteriorate, elements in the resistivity barrier layers 420 and 480 may be diffused into the memory cell MC. For example, the elements in the resistivity barrier layers 420 and 480 may be diffused into the variable resistance layer 450. Here, the elements in the resistivity barrier layers 420 and 480 may each be at least one of tungsten (W), silicon (Si), or a combination thereof.

When the elements in the resistivity barrier layers 420 and 480 are diffused into the variable resistance layer 450, the variable resistance layer 450 may be damaged. In order to reduce the damage to the variable resistance layer 450, the first diffusion barrier layer 430 may be formed between the first resistivity barrier layer 420 and the variable resistance layer 450, and the second diffusion barrier layer 470 may be formed between the second resistivity barrier layer 480 and the variable resistance layer 450. The first diffusion barrier layer 430 may reduce the diffusion of the element from the first resistivity barrier layer 420 into the variable resistance layer 450, and the second diffusion barrier layer 470 may reduce the diffusion of the element from the second resistivity barrier layer 480 into the variable resistance layer 450. Accordingly, it is possible to prevent the memory cell MC from being damaged by the elements included in the resistivity barrier layers 420 and 480.

Grain boundaries in the diffusion barrier layers 430 and 470 may be used as paths for the elements from the resistivity barrier layers 420 and 480 to diffuse into the variable resistance layer 450. Accordingly, according to an embodiment of the present disclosure, another element may be located at grain boundaries of metal elements in the diffusion barrier layers 430 and 470. For example, in processes of forming the diffusion barrier layers 430 and 470, a nitrogen element (N) may be located at a grain boundary of tungsten (W) or titanium (Ti). By blocking diffusion paths through the grain boundaries with the nitrogen element (N), it is possible to reduce the diffusion of the elements from the resistivity barrier layers 420 and 480 into the variable resistance layer 450. In other words, the diffusion barrier layers 430 and 470 may reduce or prevent the diffusion of the elements from the resistivity barrier layers 420 and 480 into the variable resistance layer 450, and thus may prevent the memory cell MC from being damaged.

According to other embodiments, at least one of the first resistivity barrier layer 420, the first diffusion barrier layer 430, the second diffusion barrier layer 470, and the second resistivity barrier layer 480 may be omitted. For example, the first resistivity barrier layer 420 and the first diffusion barrier layer 430 may be formed between the first conductive layer 410 and the first electrode layer 440, and processes of forming the second diffusion barrier layer 470 and the second resistivity barrier layer 480 may be omitted. In an alternate configuration, the second diffusion barrier layer 470 and the second resistivity barrier layer 480 may be formed between the second conductive layer 490 and the second electrode layer 460, and processes of forming the first resistivity barrier layer 420 and the first diffusion barrier layer 430 may be omitted.

Alternatively, the formation order of at least one of the first resistivity barrier layer 420, the first diffusion barrier layer 430, the second resistivity barrier layer 480, and the second diffusion barrier layer 470 may be changed. For example, the first resistivity barrier layer 420 may be formed on the first conductive layer 410, and the first electrode layer 440 may be formed on the first resistivity barrier layer 420. Subsequently, the first diffusion barrier layer 430 may be formed on the first electrode layer 440, and the variable resistance layer 450 may be formed on the first diffusion barrier layer 430. In an alternate configuration, the first resistivity barrier layer 420 and the first diffusion barrier layer 430 may be sequentially formed on the first electrode layer 440. Subsequently, the variable resistance layer 450 may be formed on the first diffusion barrier layer 430.

According to the manufacturing method described above, the first diffusion barrier layer 430 may be formed between the first resistivity barrier layer 420 and the first electrode layer 440, and the second diffusion barrier layer 470 may be formed between the second resistivity barrier layer 480 and the second electrode layer 460. The diffusion barrier layers 430 and 470 may reduce the diffusion of the elements from the resistivity barrier layers 420 and 480 into the variable resistance layer 450. Accordingly, it is possible to reduce or prevent the damage to the memory cell MC.

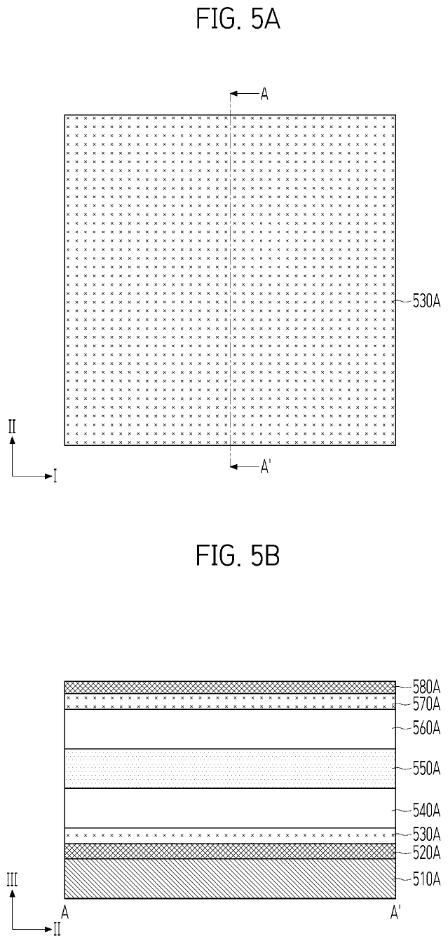

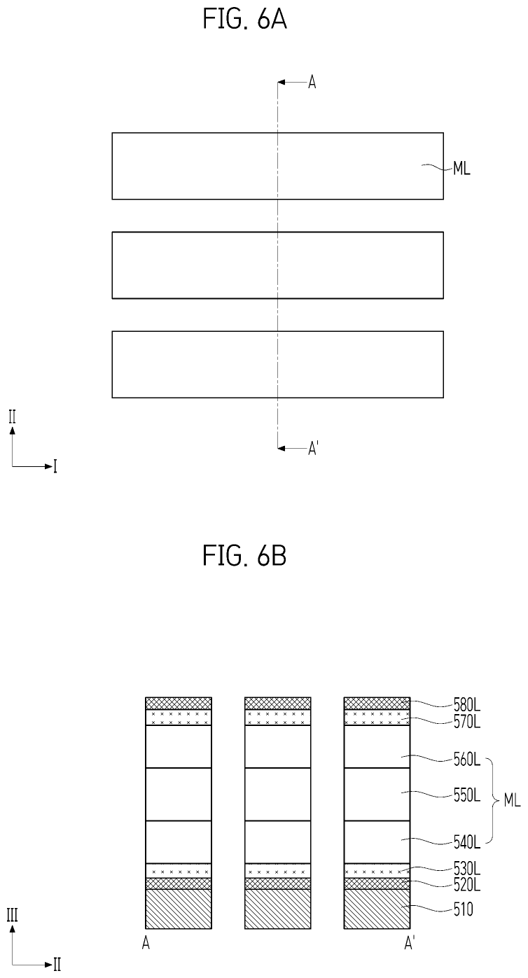

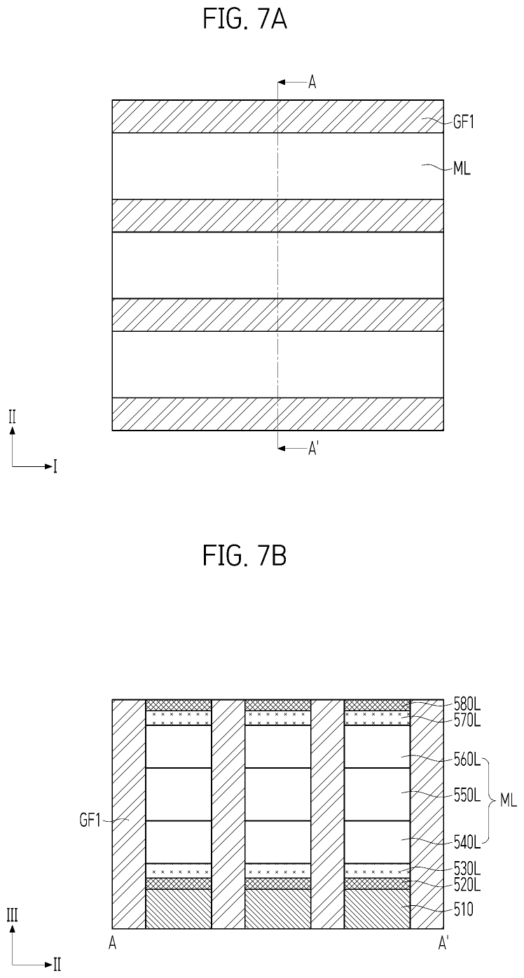

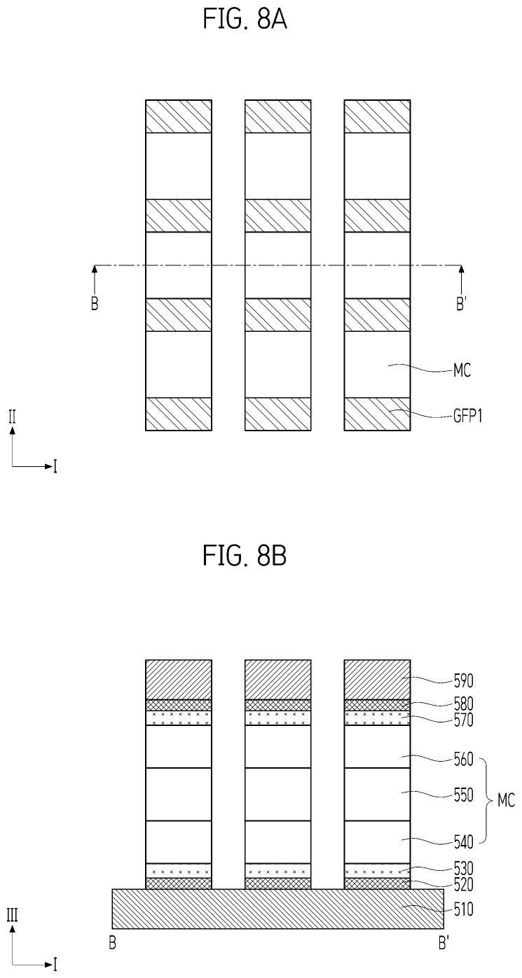

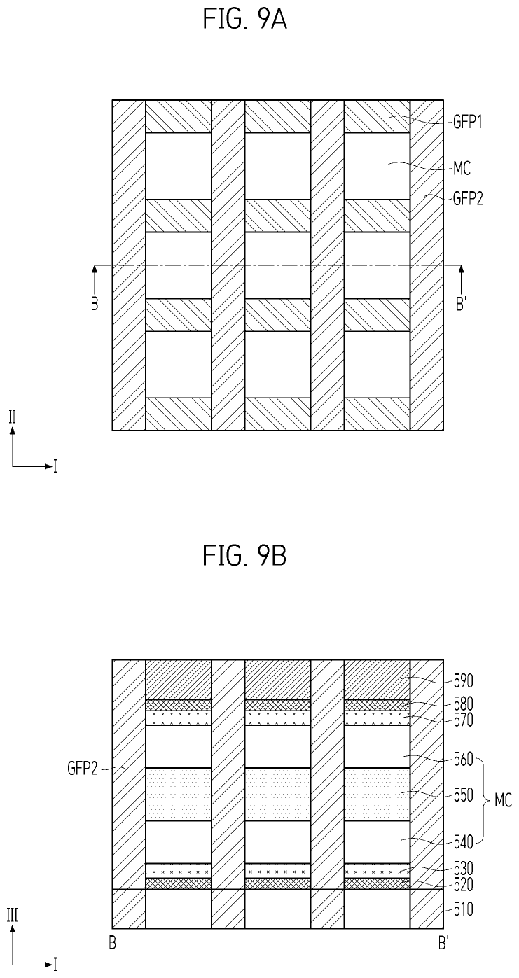

FIGS. 5A to 9B illustrate a manufacturing method of a semiconductor device in accordance with an embodiment. FIGS. 5A, 6A, 7A, 8A, and 9A may be plan views, and FIGS. 5B, 6B, 7B, 8B, and 9B may be cross-sectional views taken along line A-A′ or line B-B′ of FIGS. 5A, 6A, 7A, 8A, and 9A, respectively. Hereinafter, the content overlapping with the previously described content will be omitted.

Referring to FIGS. 5A and 5B, a first conductive layer 510A may be formed over a substrate (not illustrated). Subsequently, a first resistivity barrier layer 520A may be formed on the first conductive layer 510A. The first resistivity barrier layer 520A may be formed using at least one of an RF sputtering method, a DC sputtering method, an ALD method, and a CVD method. The first resistivity barrier layer 520A may include tungsten, silicon, or both. For example, the first resistivity barrier layer 520A may include WSiN.

Subsequently, a first diffusion barrier layer 530A may be formed on the first resistivity barrier layer 520A. The first diffusion barrier layer 530A may be formed using at least one of an RF sputtering method, a DC sputtering method, an ALD method, and a CVD method. The first diffusion barrier layer 530A may include tungsten nitride (WN), titanium nitride (TiN), or a combination thereof.

Subsequently, a first electrode layer 540A may be formed on the first diffusion barrier layer 530A. A variable resistance layer 550A may be formed on the first electrode layer 540A. A second electrode layer 560A may be formed on the variable resistance layer 550A.

A second diffusion barrier layer 570A may be formed on the second electrode layer 560A. The second diffusion barrier layer 570A may be formed using at least one of an RF sputtering method, a DC sputtering method, an ALD method, and a CVD method. The second diffusion barrier layer 570A may include tungsten nitride (WN), titanium nitride (TiN), or a combination thereof.

Subsequently, a second resistivity barrier layer 580A may be formed on the second diffusion barrier layer 570A. The second resistivity barrier layer 580A may be formed using at least one of an RF sputtering method, a DC sputtering method, an ALD method, and a CVD method. The second resistivity barrier layer 580A may include tungsten, silicon, or both. For example, the second resistivity barrier layer 580A may include WSiN.

Referring to FIGS. 6A and 6B, a second resistivity barrier line 580L and a second diffusion barrier line 570L may be formed by etching the second resistivity barrier layer 580A and the second diffusion barrier layer 570A so that the second resistivity barrier line 580L and the second diffusion barrier line 570L extend in a first direction I.

Subsequently, a plurality of memory lines ML may be formed. For example, the plurality of memory lines ML, each of which includes a second electrode line 560L, a variable resistance line 550L, and a first electrode line 540L, may be formed by etching the second electrode layer 560A, the variable resistance layer 550A, and the first electrode layer 540A. Here, each of the plurality of memory lines ML may extend in the first direction I when viewed in a plan view, and the plurality of memory lines ML may be aligned in parallel in a second direction II.

Subsequently, a first diffusion barrier line 530L and a first resistivity barrier line 520L may be formed by etching the first diffusion barrier layer 530A and the first resistivity barrier layer 520A so that the first diffusion barrier line 530L and the first resistivity barrier line 520L extend in the first direction I when viewed in a plan view.

Subsequently, a first conductive line 510 may be formed by etching the first conductive layer 510A so that the first conductive line 510 extends in the first direction I when viewed in a plan view. The first conductive line 510 may be a word line or a bit line.

Referring to FIGS. 7A and 7B, first gap fill layers GF1 may be formed between the plurality of memory lines ML. For example, the first gap fill layers GF1 may be respectively formed between the plurality of memory lines ML spaced apart from each other in the second direction II intersecting the first direction I. Here, the first gap fill layers GF1 may extend in the first direction I when viewed in a plan view. The first gap fill layers GF1 may each include an insulating material such as oxide.

Referring to FIGS. 8A and 8B, a second conductive line 590 may be formed. First, a second conductive layer (not illustrated) may be formed on the plurality of memory lines ML and the first gap fill layers GF1. Subsequently, the second conductive line 590 may be formed by etching the second conductive layer (not illustrated) so that the second conductive line 590 extends in the second direction II when viewed in a plan view. The second conductive line 590 may be a word line or a bit line. For example, when the first conductive line 510 is a word line, the second conductive line 590 may be a bit line. On the other hand, when the first conductive line 510 is a bit line, the second conductive line 590 may be a word line.

Subsequently, a second resistivity barrier pattern 580 and a second diffusion barrier pattern 570 may be formed by etching the second resistivity barrier line 580L and the second diffusion barrier line 570L, e.g., using the second conductive line 590 as an etch barrier. Consequently, multiple second resistivity barrier patterns 580 may be formed to be arranged in the first direction I and the second direction II, and multiple second diffusion barrier patterns 570 may be formed to be arranged in the first direction I and the second direction II.

Subsequently, a memory cell MC may be formed. For example, the memory cell MC, which includes a second electrode pattern 560, a variable resistance pattern 550, and a first electrode pattern 540, may be formed by etching the second electrode line 560L, the variable resistance line 550L, and the first electrode line 540L. Here, multiple memory cells MC may be formed to be arranged in the first direction I and the second direction II.

Subsequently, a first diffusion barrier pattern 530 and a first resistivity barrier pattern 520 may be formed by etching the first diffusion barrier line 530L and the first resistivity barrier line 520L. Consequently, multiple first diffusion barrier patterns 530 may be formed to be arranged in the first direction I and the second direction II, and multiple first resistivity barrier patterns 520 may be formed to be arranged in the first direction I and the second direction II. Through the above-described etching processes, each of the first gap fill layers GF1 may be separated into multiple first gap fill patterns GFP1 in the first direction I.

Referring to FIGS. 9A and 9B, second gap fill patterns GFP2 may be formed between memory cells MC. For example, the second gap fill patterns GFP2 may be respectively formed between memory cells MC spaced apart from each other in the first direction I. First, a second gap fill layer (not illustrated) may be formed to fill spaces between the memory cells MC that are spaced apart from each other in the first direction I and to cover the multiple memory cells MC. Subsequently, the second gap fill patterns GFP2 may be formed by planarizing the second gap fill layer (not illustrated) until an upper surface of the second conductive line 590 is exposed. Here, the second gap fill patterns GFP2 may extend in the second direction II when viewed in a plan view, and may each include an insulating material such as oxide.

The memory cell MC may operate by receiving a voltage or a current supplied through the first conductive line 510 or the second conductive line 590. When the memory cell MC operates, a spike current may occur. The resistivity barrier patterns 520 and 580 may prevent or reduce damage to the memory cell MC due to the spike current.

When the memory cell MC is repeatedly operated, the resistivity barrier patterns 520 and 580 may deteriorate. For example, the resistivity barrier patterns 520 and 580 may agglomerate. When the resistivity barrier patterns 520 and 580 deteriorate, elements included in the resistivity barrier patterns 520 and 580 may be diffused into the memory cell MC. For example, at least one of tungsten (W) and silicon (Si) included in the resistivity barrier patterns 520 and 580 may be diffused into the variable resistance pattern 550 of the memory cell MC.

When the elements included in the resistivity barrier patterns 520 and 580 are diffused into the memory cell MC, the memory cell MC may be damaged. In order to reduce the damage to the memory cell MC, the first diffusion barrier pattern 530 may be formed between the first resistivity barrier pattern 520 and the variable resistance pattern 550, and the second diffusion barrier pattern 570 may be formed between the second resistivity barrier pattern 580 and the variable resistance pattern 550. Here, the first diffusion barrier pattern 530 may prevent the element included in the first resistivity barrier pattern 520 from being diffused into the variable resistance pattern 550, and the second diffusion barrier pattern 570 may prevent the element included in the second resistivity barrier pattern 580 from being diffused into the variable resistance pattern 550. Accordingly, it is possible to reduce or prevent the damage to the memory cell MC by the elements included in the resistivity barrier patterns 520 and 580.

According to other embodiments, one or more of the resistivity barrier patterns 520 and 580 and the diffusion barrier patterns 530 and 570 may be omitted. Alternatively, the formation order of one or more of the resistivity barrier patterns 520 and 580 and the diffusion barrier patterns 530 and 570 may be changed.

According to the manufacturing method described above, the diffusion barrier patterns 530 and 570 may reduce the diffusion of the elements included in the resistivity barrier patterns 520 and 580 into the variable resistance pattern 550. Accordingly, the diffusion barrier patterns 530 and 570 may reduce or prevent the damage to the memory cell MC.

Although embodiments according to the technical idea of the present disclosure have been described above with reference to the accompanying drawings, this is only for explaining the embodiments according to the concept of the present disclosure, and the present disclosure is not limited to the above embodiments. Various types of substitutions, modifications, and changes for the embodiments may be made by those skilled in the art, to which the present disclosure pertains, without departing from the technical idea of the present disclosure defined in the following claims, and it should be construed that these substitutions, modifications, and changes belong to the scope of the present disclosure.

What is claimed is:

1. A semiconductor device comprising:
a first conductive line;
a second conductive line located over the first conductive line, wherein the first conductive line and the second conductive line extend in different directions, intersecting each other;
a variable resistance e pattern located between the first conductive line and the second conductive line;
a first electrode pattern located between the first conductive line and the variable resistance pattern;
a first resistivity barrier pattern located between the first conductive line and the first electrode pattern; and
a first diffusion barrier pattern located between the first resistivity barrier pattern and the first electrode pattern.

2. The semiconductor device of claim 1, wherein the first diffusion barrier pattern includes tungsten nitride (WN) or titanium nitride (TiN).

3. The semiconductor device of claim 2, wherein the first resistivity barrier pattern includes WSiN.

4. The semiconductor device of claim 2, wherein the first diffusion barrier pattern prevents an element included in the first resistivity barrier pattern from being diffused into the variable resistance pattern.

5. The semiconductor device of claim 4, wherein the element includes tungsten, silicon, or both.

6. The semiconductor device of claim 1, wherein a resistivity of the first diffusion barrier pattern is lower than a resistivity of the first resistivity barrier pattern.

7. The semiconductor device of claim 1, wherein the first resistivity barrier pattern has a first thickness, and the first diffusion barrier pattern has a second thickness that is greater than the first thickness.

8. The semiconductor device of claim 1, further comprising:
a second electrode pattern located between the variable resistance pattern and the second conductive line;
a second resistivity barrier pattern located between the second electrode pattern and the second conductive line; and
a second diffusion barrier pattern located between the second electrode pattern and the second resistivity barrier pattern.

9. The semiconductor device of claim 8, wherein the second diffusion barrier pattern includes tungsten nitride (WN) or titanium nitride (TiN).

10. The semiconductor device of claim 8, wherein the second resistivity barrier pattern includes WSiN.

11. The semiconductor device of claim 8, wherein the second diffusion barrier pattern prevents an element included in the second resistivity barrier pattern from being diffused into the variable resistance pattern.

12. The semiconductor device of claim 8, wherein a resistivity of the second diffusion barrier pattern is lower than a resistivity of the second resistivity barrier pattern.

13. The semiconductor device of claim 8, wherein the second resistivity barrier pattern has a third thickness, and the second diffusion barrier pattern has a fourth thickness that is greater than the third thickness.

14. A manufacturing method of a semiconductor device, the manufacturing method comprising:
forming a first resistivity barrier layer over a first conductive layer;
forming a first diffusion barrier layer over the first resistivity barrier layer;
forming a first electrode layer over the first diffusion barrier layer;
forming a variable resistance layer over the first electrode layer;
forming a second electrode layer over the variable resistance layer; and
forming a second conductive layer over the second electrode layer.

15. The manufacturing method of claim 14, further comprising:
forming a second diffusion barrier layer over the second electrode layer; and
forming a second resistivity barrier layer over the second diffusion barrier layer.

16. The manufacturing method of claim 15, wherein at least one of the first diffusion barrier layer and the second diffusion barrier layer includes tungsten nitride (WN) or titanium nitride (TIN).

17. The manufacturing method of claim 16, wherein either the first resistivity barrier layer, the second resistivity barrier layer, or both include WSiN.

18. The manufacturing method of claim 16, wherein the first diffusion barrier layer prevents an element included in the first resistivity barrier layer from being diffused into the variable resistance layer, and the second diffusion barrier layer prevents an element included in the second resistivity barrier layer from being diffused into the variable resistance layer.

19. The manufacturing method of claim 18, wherein the element included in each of the first resistivity barrier layer and the second resistivity barrier layer includes tungsten, silicon, or both.

20. The manufacturing method of claim 15, wherein a resistivity of the first diffusion barrier layer is lower than a resistivity of the first resistivity barrier layer, and a resistivity of the second diffusion barrier layer is lower than a resistivity of the second resistivity barrier layer.

21. The manufacturing method of claim 14, wherein the first resistivity barrier layer has a first thickness, and the first diffusion barrier layer has a second thickness that is greater than the first thickness.

22. The manufacturing method of claim 15, wherein the second resistivity barrier layer has a third thickness, and the second diffusion barrier layer has a fourth thickness that is greater than the third thickness.

23. A manufacturing method of a semiconductor device, the manufacturing method comprising:
forming a first conductive layer;
forming a first resistivity barrier layer over the first conductive layer;
forming a first diffusion barrier layer over the first resistivity barrier layer;
forming a first electrode layer over the first diffusion barrier layer;
forming a variable resistance layer over the first electrode layer;
forming a second electrode layer over the variable resistance layer;
forming a memory line that includes a second electrode line, a variable resistance line, and a first electrode line by etching the second electrode layer, the variable resistance layer, and the first electrode layer in a first direction;
forming a first diffusion barrier line and a first resistivity barrier line by etching the first diffusion barrier layer and the first resistivity barrier layer in the first direction;
forming a second conductive layer over the memory line;
forming a second conductive line by etching the second conductive layer in a second direction that intersects the first direction;
forming a memory cell that includes a second electrode pattern, a variable resistance pattern, and a first electrode pattern by etching the memory line in the second direction; and
forming a first diffusion barrier pattern and a first resistivity barrier pattern by etching the first diffusion barrier line and the first resistivity barrier line in the second direction.

24. The manufacturing method of claim 23, further comprising:
forming a second diffusion barrier layer over the second electrode layer; and
forming a second resistivity barrier layer over the second diffusion barrier layer.

25. The manufacturing method of claim 24, further comprising forming a second resistivity barrier line and a second diffusion barrier line by etching the second resistivity barrier layer and the second diffusion barrier layer in the first direction.

26. The manufacturing method of claim 25, further comprising forming a second resistivity barrier pattern and a second diffusion barrier pattern by etching the second resistivity barrier line and the second diffusion barrier line in the second direction.

27. The manufacturing method of claim 26, wherein the first diffusion barrier pattern prevents an element included in the first resistivity barrier pattern from being diffused into the variable resistance pattern, and the second diffusion barrier pattern prevents an element included in the second resistivity barrier pattern from being diffused into the variable resistance pattern.

28. The manufacturing method of claim 27, wherein the element includes tungsten, silicon, or both.

29. The manufacturing method of claim 24, wherein at least one of the first diffusion barrier layer and the second diffusion barrier layer includes tungsten nitride (WN) or titanium nitride (TiN).

30. The manufacturing method of claim 24, wherein either the first resistivity barrier layer, the second resistivity barrier layer, or both include WSiN.

31. The manufacturing method of claim 24, wherein a resistivity of the first diffusion barrier layer is lower than a resistivity of the first resistivity barrier layer, and a resistivity of the second diffusion barrier layer is lower than a resistivity of the second resistivity barrier layer.

32. The manufacturing method of claim 23, wherein the first resistivity barrier layer has a first thickness, and the first diffusion barrier layer has a second thickness that is greater than the first thickness.

33. The manufacturing method of claim 24, wherein the second resistivity barrier layer has a third thickness, and the second diffusion barrier layer has a fourth thickness that is greater than the third thickness.
